(19) United States
(12) Patent Application Publication
(10) Pub. No.: US 2009/0213616 A1
(43) Pub. Date: Aug. 27, 2009

(54) CO-FUNCTIONAL MULTI-LIGHT SOURCE LUMENAIRES AND COMPONENTS THEREOF

(76) Inventor: Jerome H. Simon, Newton, MA (US)

Correspondence Address: BURNS & LEVINSON, LLP, 125 SUMMER STREET, BOSTON, MA, 02110, US

(21) Appl. No.: 12/389,896

(22) Filed: Feb. 20, 2009

Related U.S. Application Data
(60) Provisional application No. 61/066,612, filed on Feb. 21, 2008.

(51) Int. Cl. H01L 33/00; F21V 1/00

(52) U.S. Cl. 362/555; 362/235

(57) ABSTRACT

A lumenaire system for providing illumination by distributing and mixing light from multiple sources of illumination which includes a first light source providing Lambertian light radiation and a second light source providing collimated illumination. There is a prismatic light guide structure having at least two functions, the first function being to refract the light radiation from the first light source disposed as to at least partially surround the light source, and the second function is to guide and distribute light from the second light source so as to mix it with light from the first light source.

### REFERENCE TO RELATED APPLICATIONS

The present application is based on and claims the priority of provisional application, Ser. No. 61/066,612 filed Feb. 21, 2008. The substance of that application is hereby incorporated herein by reference.

### FIELD OF INVENTION

This invention relates generally to the lighting art, and, more particularly to a luminaire that distributes light from multiple light source inputs.

### SUMMARY OF THE INVENTION

The present invention provides uniform light distribution within a specific area from lumenaires and lighting devices that distribute light from multiple light source inputs.

The invention also provides specific light functions from lumenaires that distribute light from multiple light sources.

The luminaire system of the present invention provides continuity of light distribution and illumination from multiple light source inputs that are alternately off or on at varying intensities with the lumenaire.

The invention also provides a uniform and continuous light distribution from either or solar (natural) and artificial sources.

The present invention of a lumenaire provides uniform and continuous light distribution from two types of artificial source inputs simultaneously or with differing ratios between the sources.

The invention also provides a lumenaire that has a moveable control for one or more types of illumination simultaneously.

### BRIEF DESCRIPTION OF THE DRAWINGS

These and other objects, features and advantages will be apparent from the following detailed description of preferred embodiments taken in conjunction with the accompanying drawings in which:

FIG. 1 is a three dimensional diagram of a lumenaire system in which light guides provide the functions of guiding light from a first source and refracting light from a second source.

FIG. 1A is a three dimensional diagram showing a lumenaire system similar to that of FIG. 1 further illustrating collimating elements at the ends of the light guides.

FIG. 1B is a three dimensional diagram of a lumenaire system similar to that of FIG. 1 illustrating an alternative cross sectional shape of the light guide.

FIG. 1C is a three dimensional diagram of a lumenaire system similar to that of FIG. 1 illustrating a geometry for tapering the light guides.

FIG. 1D is a three dimensional diagram of a lumenaire system similar to that of FIG. 1C with alternative geometry for tapering the light guides.

FIG. 2 is a three dimensional diagram of a lumenaire system comprising a tubular structure of linear prisms that transports light from multiple light sources.

FIG. 3 is a three dimensional diagram of a lumenaire system comprising a prismatic structure that reflects, directs and mixes light from multiple light sources and comprises a linear light source.

FIG. 3A is a three dimensional diagram of a lumenaire system similar to that in FIG. 3, the prismatic structure having an alternate shape and the linear light source comprising a reflector.

FIG. 4 is a cross-sectional view of a prismatic structure illustrated in FIG. 3 further illustrating a purpose for changing the curvature of the structure.

FIG. 4A is a cross-sectional view of a similar prismatic structure illustrated in FIG. 4 having a change in the curvature of the structure.

FIG. 4B is a cross-sectional view of a ganged grouping of prismatic structures as illustrated in FIGS. 4 and 4A.

FIG. 4C is a cross-sectional view of a ganged group of prismatic structures as illustrated in FIG. 4B showing an alternately inverted arrangement in curvatures.

FIG. 5 is a three dimensional diagram of a lumenaire panel comprising an LED surrounded by a radially collimating optic further partially surrounded by a reflector.

FIG. 5A is a three dimensional diagram of a lumenaire panel similar to that of FIG. 5 showing both sides of the panel being exposed.

FIG. 6 is a three dimensional diagram of a lumenaire comprising a grid of panels similar to those illustrated in FIG. 5.

FIG. 6A is a three dimensional diagram of a lumenaire comprising a grid of panels as illustrated in FIG. 6 with the addition of linear light sources projecting light through the grid.

FIG. 6B is a three dimensional diagram of a lumenaire comprising linear arrangements of panels similar to those illustrated in FIG. 5.

FIG. 6C is a three dimensional diagram of linear configurations as illustrated in FIG. 6B showing that each of these linear configurations can be made to tilt about an axis.

FIG. 6D is an edge view diagram of the linear configurations as described in FIG. 6C illustrating that the tilting axes can be disposed at differing points along the sections of the configurations.

FIG. 6E is a three dimensional view of a lumenaire illustrating linear configurations of panels shown in FIG. 6C tilted at an angle to allow angularly disposed light to pass through.

### DETAILED DESCRIPTION OF PREFERRED EMBODIMENTS

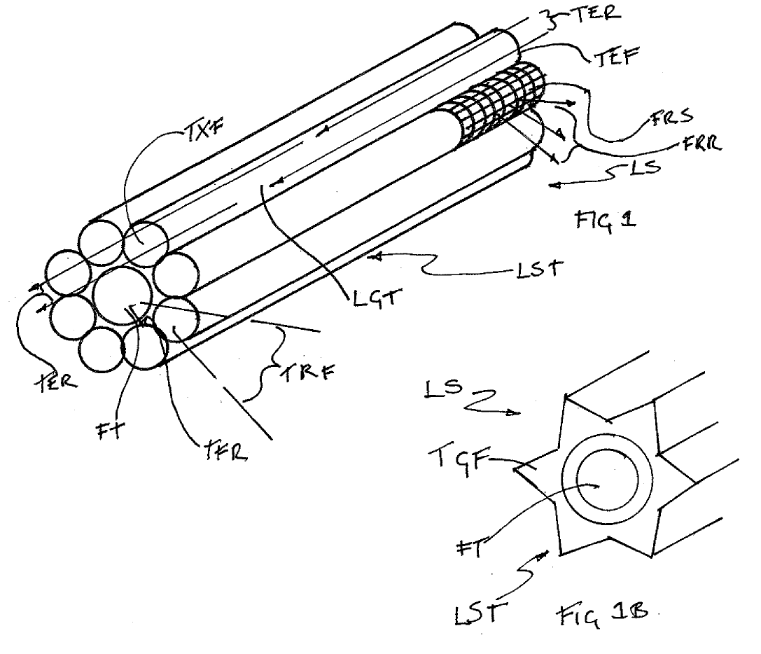

FIG. 1 is an isometric diagram of lumenaire system LS comprising a group of typical light guides LGT disposed as to form a tube LST which is shown to at least partially surround linear light source FT. Typical light beam TER enters the entry face TEF of typical light guide LGT and exits the exit face TXF as typical beam TER. In the embodiment of FIG. 1, typical light guide LGT acts to provide efficient continuity for typical beam TER, yet in other embodiments the surface of LGT can be at least partially frosted or comprise refracting elements FRS so that some of typical beam TER is extracted by said frosting or said refracting elements FRS of said frosting as rays FRR. Typical light guide LGT of tube LST which is said to at least partially surround linear light source FT refracts typical light ray TFR emanating from linear light source FT as typical refracted rays TRF. The above said description illustrates that light guide LGT has two functions, one to act as a light guide for a first light source, and two to act as a refracting element to said first light sources and to a second light source.

FIG. 1A is an isometric diagram of a lumenaire system LS similar in components and function to the lumenaire system as in FIG. 1 further comprising typical collimating light sources PTC which projects typical collimated beam TER into the entry face TEF of and through typical light guide LGT as beam PCB out of typical exit face TXF as exit beam TER. Typical collimating sources PTC can be comprised of quasi point light sources such as LEDs, the light emanating from which collimated by refractive means such as lenses or reflective means such as but not limited to parabolic, spherical, or ellipsoidal reflectors or combined refractors and reflectors, or from the ends of fiber optics which in some embodiment may be alternately disposed with said quasi point light sources.

FIG. 1B is an isometric detail diagram of a lumenaire system LS similar in components and function to the lumenaire system described in FIG. 1 differing in that the typical light guide LGT shown as substantially cylindrical in section as in FIG. 1 is shown as being substantially triangular as typical triangular light guide TGT in FIG. 1B. Other cross-sectional shapes are possible such as ovals and polyhedrons.

FIG. 1C is an isometric diagram of a lumenaire system TGB similar to that of FIG. 1 differing in that, while the typical light guides LGT of FIG. 1 are shown to be substantially cylindrical and have equal cross-sectional diameters along their lengths, the typical light guides TAG of FIG. 1C have a taper incorporated along their lengths, formed by a substantially planar surface TAP intersecting at an angle to the cylindrical surface of typical light guides TAG. The function of light guides TAG is that of a tapered light guide which has known and common optical use to allow light that has been projected into the wider end of the guide WEF to be extracted along the guide at a rate that is due in part to the angle of taper along the length of the guide. This principle is illustrated in FIG. 1C by beam TER entering the wide end of typical tapered light guide TAG, which extracts rays ELR along its length. Said planar surface TAP could further comprise refracting elements to control the distribution of said extracted light. In this embodiment a portion of TER passes through typical light guide TAG as rays ELR other than light lost due to the inefficiencies of the system. The tapered light guides TAG are at least partially transparent and partially surround linear light source TF allowing emanating light rays TFR to pass through as refracted rays RFR which mix with extracted rays ELR. Thus lumenaire system TGB has the function of mixing two light sources, namely the one producing beam TER which may be a collimating source such as PTC as described in FIG. 1 or a single collimator projecting into the grouping of typical light guides TAG or sunlight entering entry face WEF directly or through fiber optics, and the second light source which is the linear light source TF.

FIG. 1D is a three dimensional diagram of a lumenaire system TFB similar in function to the lumenaire system shown in FIG. 1C, differing in that the typical tapered light guides TAG of FIG. 1F are shaped as substantially elongated cones having entry face WEF into which beam TER is projected, being a large diameter LD tapering into a small diameter SD at the opposite end of tapered light guide TAG. In other embodiments typical light guide TAG may taper from the wide entry face WEF into a point. At least a portion of the surface of said tapered light guides could comprise prismatic elements.

FIG. 2 is a three-dimensional diagram of a lumenaire system LGL designed to transport light from multiple types of light sources, comprising a substantially tubular arrangement of typical light guides LGT, each having an entry face PEF allowing typical beam TER to pass into and through typical light guide LGF exiting exit face PXF as beam TER. The inner surfaces IS of typical light guides LGT are disposed as to form hollow light guide ILG at least partially surrounded by typical light guides LGT.

Light guide ILG has an entry face IE and an exit face IX allowing beam TWB to enter, pass through, and exit said guide ILG. It should be noted that the entry faces of the light guides in FIGS. 1 through 2 can receive light from either artificial or natural light. As described in FIG. 1, the outer surface or inner surface of light guide(s) LGT can be refractive or, as in FIG. 1C or 1D, typical light guide(s) LGT can comprise a tapered element.

FIG. 3 is a three-dimensional diagram of a lumenaire system LS comprising a linear prismatic structure LPS, further comprising typical linear prisms TLP disposed along the linear prismatic structure LPS. The function(s) of linear prism LPS is further explained and incorporated herein by reference in my Patent U.S. Pat. No. 6,540,382. Each typical linear prism TLP comprises typical entry surfaces TES, and typical exit surfaces TXS which can be part of a common surface CS. Linear prismatic structure LPS receives, directs, and mixes light from two sources, the first source being a linear source FT the rays of which TFR are refracted by and pass through typical linear prisms LPS as rays TFX; the rays of a second light source, which may be derived from a natural source such as daylight or sunlight or from artificial means such as collimators described in FIG. 1A, (not shown in this FIG. 3) TER are internally reflected and pass through typical linear prism PS as rays TXR in the same general direction and mix with rays TFX.

FIG. 3A is a three-dimensional diagram of a lumenaire system LS similar to the lumenaire system LS in FIG. 3 differing in that typical prismatic structure LPS of FIG. 3 is curved in cross-section and the cross-section of typical prismatic structure LPS of Pig. 3 is substantially flat, resulting in the relationship and directionality between rays TFX and TXR in FIG. 3 being different from the relationship and the directionality of rays TFX and TXR of FIG. 3A. A reflectors which may be curved or flat in section may be incorporated to reflect a portion of rays TRF back and onto prism structure LPS as rays RFR. Light guide ILG has an entry face IE and an exit face IX allowing beam TWB to enter, pass through, and exit said guide. It should be noted that the entry faces of the light guides in FIGS. 1 through 2 can receive light from either or both artificial and natural light.

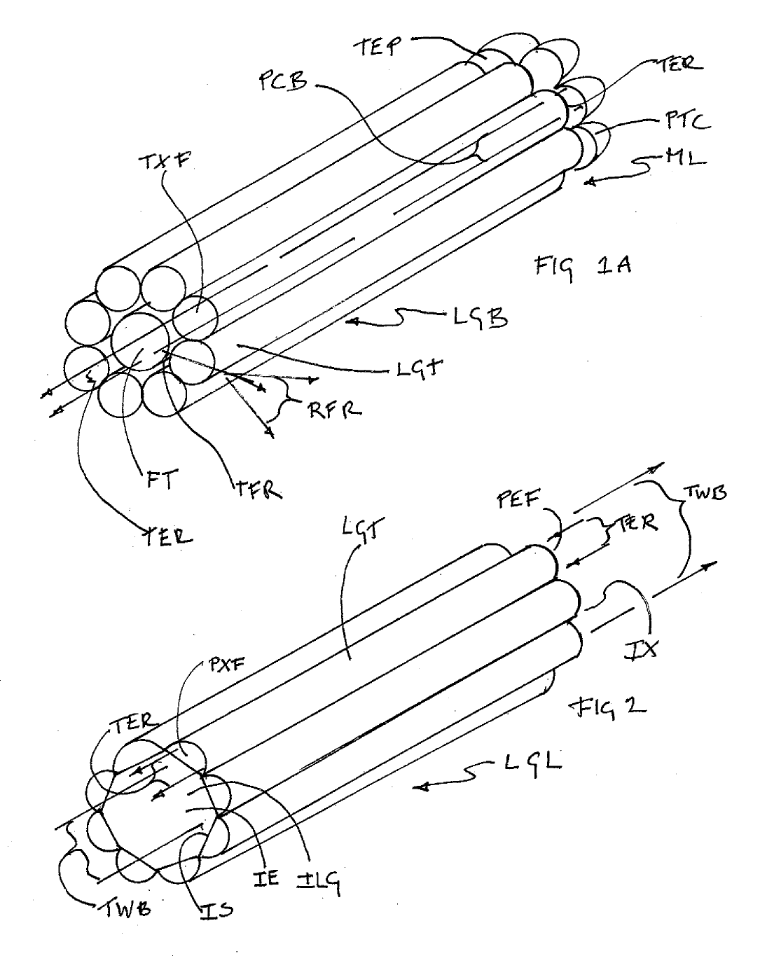

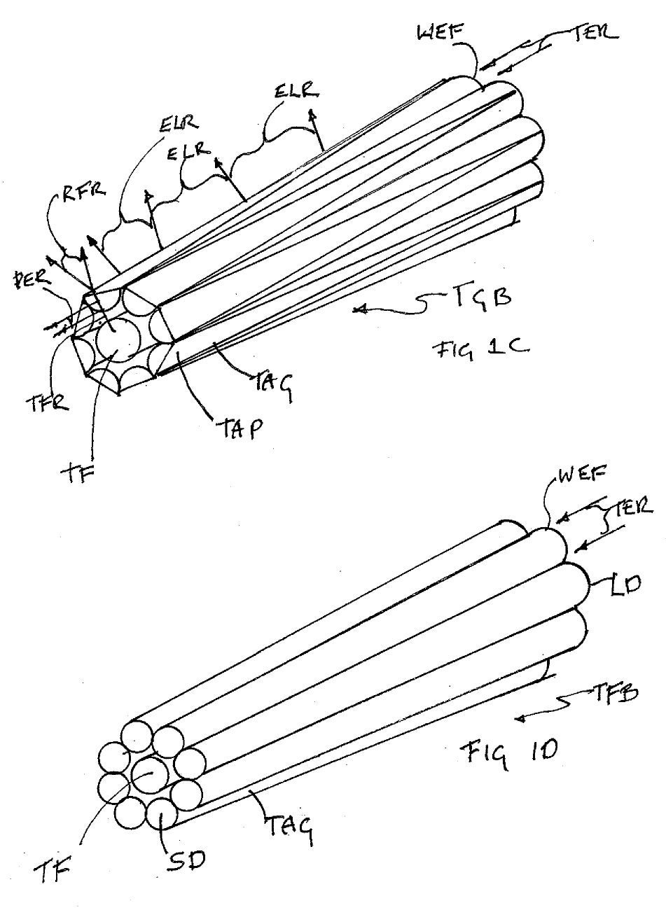

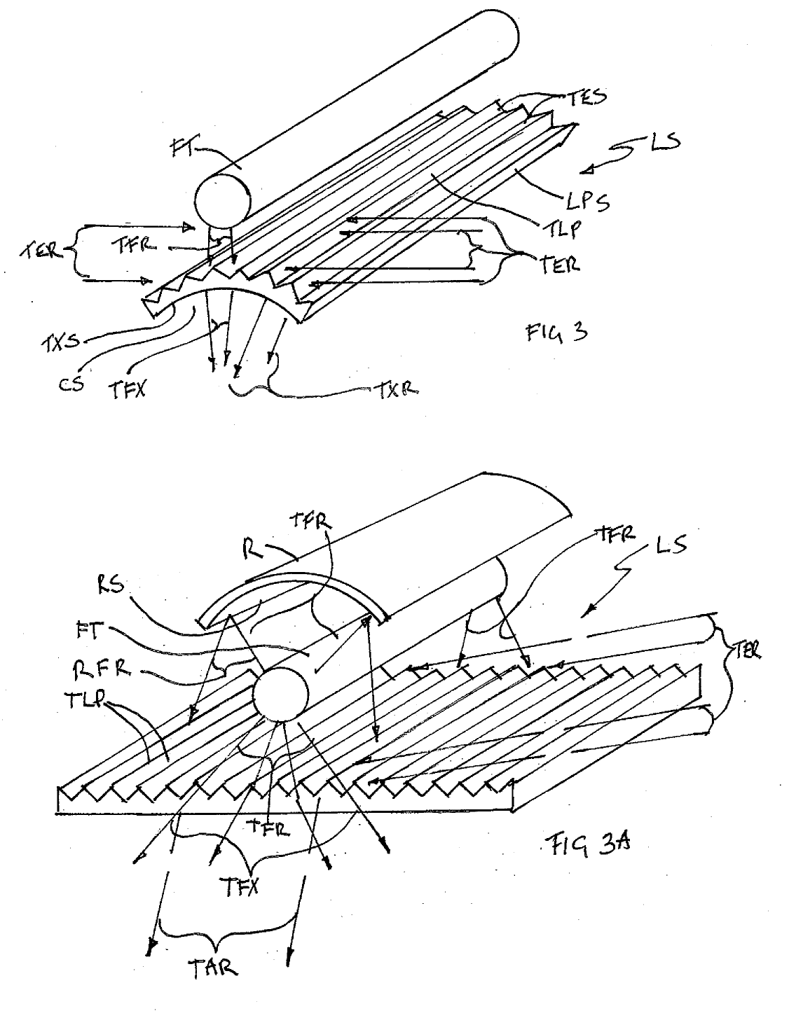

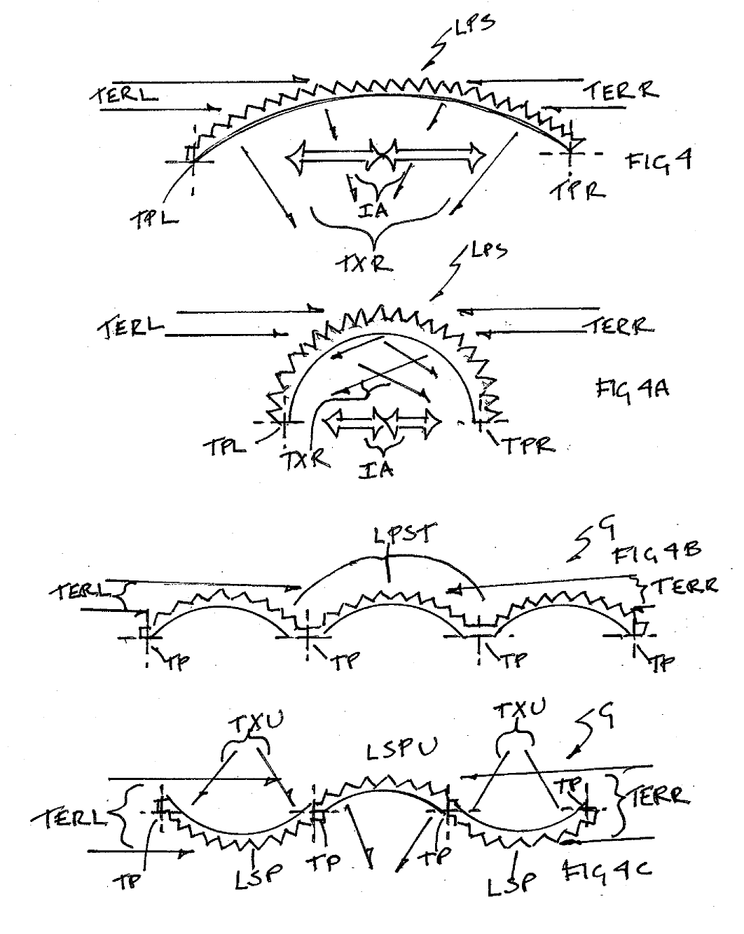

FIG. 4 is a cross-sectional view of the linear prismatic structure LPS as shown in FIG. 3 having the further capability to change its refracting function in terms of the relationship between entering beams left TERL and entering beams right TERR and the angular convergence of refracted exiting rays TXR. This said change in refracting function is achieved and illustrated by the change in curvature of linear prism structure LPS in FIG. 4 to the curvature of linear prism structure of FIG. 4A in which each said figure illustrated a different angular direction of exiting rays TXR. This said change in the curvature between the figures can be mechanically accomplished by moving designated right and left points TPPR and TPL respectively further apart and closer to together as illustrated by directional arrows IA. The function of said linear prismatic structure is disclosed in U.S. Pat. No. 6,540,382 and incorporated by reference herein.

FIG. 4B is a cross-sectional view of a ganging G of three typical linear prismatic structures LPST each having the capability and function of the linear prismatic structure LPS as illustrated in FIGS. 4 and 4A.

FIG. 4C is a cross-sectional view of a ganging G of three typical linear prismatic structures LPST similar in function to the gang G of typical linear prismatic structures LPST of FIG. 4B differing in that the centrally disposed linear prismatic structure in FIG. 4C is inverted in terms of its curvature to the linear prismatic structures LPS(s) on either side and there refract beams TER as beam TXL in the opposite direction to beam(s) TXU.

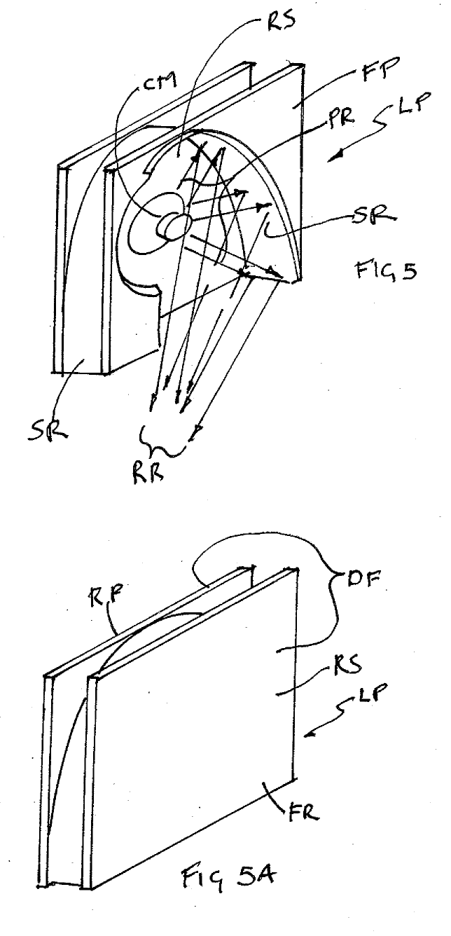

FIG. 5 is a three-dimensional diagram of a lumenaire panel LP comprising a radially collimating light source CM, further comprising a quasi point light source such as an LED at least partially surrounded by a radially collimating optic. The radially collimating optic is mounted to a panel RP, which, when the quasi point light source is an LED, would be fabricated from a material such as aluminum in order to act as a heat sink to draw off heat from the LED. Radially collimating light source CM is at least partially surrounded by a reflector SR which can be continuously curved forming an ellipse or parabola or be spherical in section. Reflector SR gathers and reflects radially projected light PR emanating from radially collimating light source CM; the shape of the projected beam RR depends upon the curvature of reflector SR. A second panel FP may also be incorporated into lumenaire panel LP. Both panels RP and FP may comprise a means of forming the shape of reflector SR and both panels may have a reflective surface RS to control the beam divergence of radially projected beam RP and or reflected beam RR. The functions and variations of lumenaire panel LP are further described and are incorporated herein by reference in my pending patent application, Ser. No. 11/635,178 and U.S. Pat. No. 5,897,201.

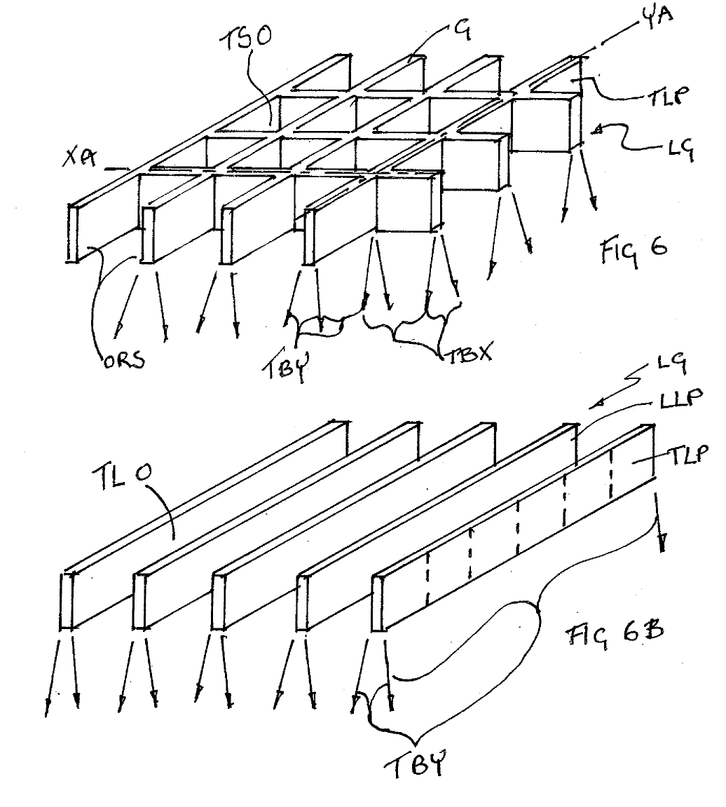

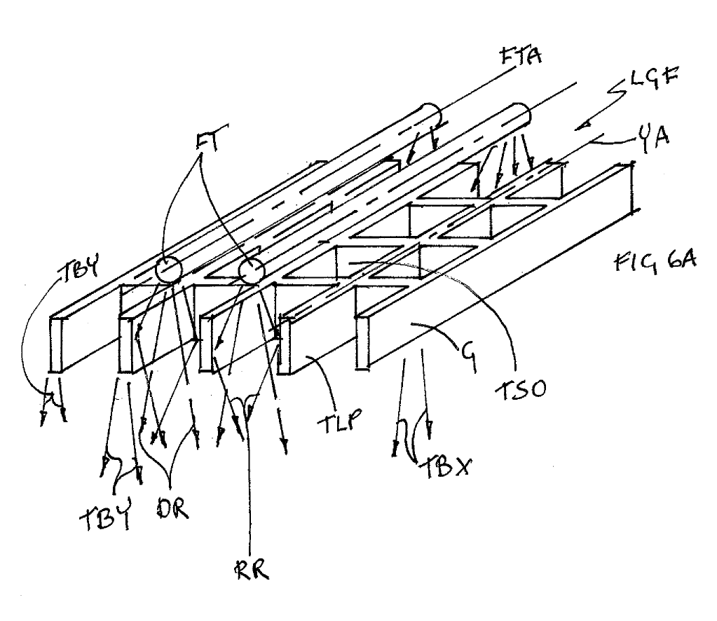

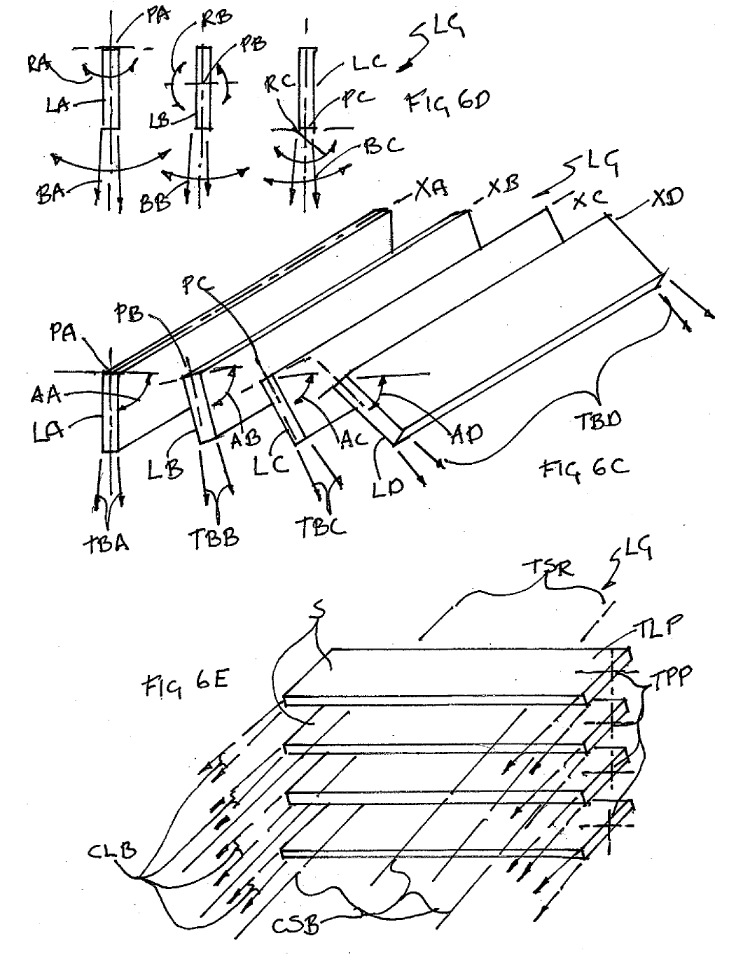

FIG. 5A is a three-dimensional view of an enclosed lumenaire panel LP similar in structure and function to the lumenaire structure shown in FIG. 5. Either or both of the outer surfaces OF of panels RR and RS can be reflective FR. The purpose of this is further described and illustrated in FIGS. 6A, 6B, 6C, 6D, and 6E.

FIG. 6 is a three-dimensional diagram of a lumenaire LG which is comprised of typical lumenaire panels TLP, similar to lumenaire panel LP as described in FIGS. 5 and 5A. Typical lumenaire panels TLP are disposed along axes XA and YA and are arranged so that lumenaire LG is in the form of a grid having typical openings TSO. The grid of lumenaire LG can be structural, the structural strength being derived from the material of the heat sinks and or the reflective surfaces or other structural material that can be added to the grid. Each of the typical lumenaire panels TLP disposed along axis XA projects a typical linear beam TBX and each of the typical lumenaire panels TLP disposed along axis YA projects a typical beam TYB. The surfaces ORS surrounding and forming typical openings TSO may have varying degrees of reflectivity. The purpose of this is further illustrated and explained herein in FIG. 6A.

FIG. 6A is a three-dimensional diagram of a lumenaire LGF similar in structure and function to the lumenaire LG in FIG. 6, differing in that typical linear light sources FT (which may be fluorescent) are disposed so that their axis FTA are substantially parallel with an axis (in this case axis YA) of grid G, and positioned so that a portion of the light emanating from linear light source FT can efficiently pass directly through typical openings TSO as rays DR while another portion of the light is reflected from surfaces ORS as reflected rays RR, grid G functioning as a reflecting baffle. Surfaces ORS can comprise various types of light control material such as reflective and refractive films as well as paints having reflecting, refracting or light absorbing properties. Rays RR and DR can mix with rays TBY and TBX that are projected from typical lumenaire panels TLP. Both linear light sources FT and typical lumenaire panels TLP may be switched independently so that illumination can be derived from one source or the other or from both sources simultaneously.

FIG. 6B is a three-dimensional diagram of a lumenaire LG, the function of which is similar to the lumenaire LG of FIG. 6, differing in that the typical lumenaire panels TLP are attached edge to edge to one another to form linear light panels LLP, each of which are further disposed substantially parallel to each other, and between forming typical linear open-ended spaces TLO through which artificial and or natural light can pass. Linear light panel LLP can be used to baffle said artificial and or natural light.

FIG. 6C is a three-dimensional diagram of a lumenaire LG the function and components of which are similar to the lumenaire LG of FIG. 6B, differing in that the linear light panel LA, LB, LC, and LD of FIG. 6C can be mechanically pivoted around axis XA, XB, XC, and XD respectively and each at differing angles AA, AB, AC and AD respectively. As the angle of each linear light panel AA, AB, AC and AD changes, so does the angle of typical beams TBA, TBB, TBC and TBD to common plane CP respectively. Note each linear light panel LA, LB, LC, and LD has a pivot point PA, PB, PC, and PD respectively located commonly at the junction of common plane CP and their respective axis XA, XB, XC and XD.

FIG. 6D is an edge view elevation of a lumenaire LG similar to the lumenaire LG of FIG. 6C illustrating that the pivot points PA, PB, and PC are disposed in different locations on their respective linear light panels LA, LB, and LC allowing a respective rotation shown in arrows RA, RB, and RC causing the rotation of beams BA, BB, and BC.

FIG. 6E is a three dimensional view of a lumenaire LG similar in function and structure to the lumenaire LG in FIG. 6C wherein the typical linear panels TLP are disposed about typical pivot points TPP as substantially at equal angles to each other. In this configuration typical linear beams CLB are substantially parallel to each other. Rays of sunlight TSR can pass between typical linear panels TLP as beams CSB and can be made to mix with parallel linear beams CLB which by mechanically pivoting typical linear panels TLP the vertical angle of the sun's rays TSR and the vertical angle rays of typical linear beam CLB can maintain parallel continuity to each other. By rotating typical linear panels TLP, said panels can function as louvers for blocking or redirecting said sunlight.

It will now be apparent to those skilled in the art that other embodiments, improvements, details, and uses can be made consistent with the letter and spirit of the foregoing disclosure and within the scope of this patent which is limited only by the following claims, construed in accordance with the patent law, including the doctrine of equivalents.

1. A lumenaire system for providing illumination by distributing and mixing light from multiple sources of illumination comprising:
a. a first light source providing Lambertian light radiation;
b. a second light source providing collimated illumination; and
c. a prismatic light guide structure having at least two functions, the first function being to refract the Lambertian light radiation from said first light source disposed as to at least partially surround said light source and the second function being to guide and distribute collimated light from the second light source so as to mix it with light from said first light source.

2. A lumenaire system as in claim 1 wherein said first light source is a linear fluorescent tube and said light guide structure is configured and disposed so as to form a tube at least partially surrounding said fluorescent tube.

3. A lumenaire system as in claim 1 where said light guide structure comprises individual rod shaped light guides refracting light emanating from said first light source.

4. A lumenaire as in claim 3 wherein at least one of said rod shape light guides further comprise a tapered surface.

5. A lumenaire as in claim 3 wherein at least one of said rod shaped light guides is tapered, the diameter of one end being larger than the diameter at the other end.

6. A lumenaire as in claim 3 wherein at least one of said rod shaped light guides comprises a diffracting surface at least partially covering a portion of said light guide.

7. A lumenaire as in claim 1 wherein the light guide structure comprises linear prisms, the sections of which are polygons.

8. A lumenaire system as in claim 3 wherein at least one individual rod shaped light guide receives comprises a light collimating component.

9. A lumenaire system as in claim 1 wherein the second type of said light source is the sun.

10. A lumenaire system for providing illumination by distributing and mixing light from multiple sources of illumination comprising:
a. a first light source providing Lambertian light radiation;
b. a second light source providing collimated illumination; and
c. a prismatic structure having at least two functions, the first function being to refract the Lambertian light radiation from said first light source; and the second function being to redirect said collimated light through internal reflection from said second light source and mix it with said light from said first light source.

11. A lumenaire system as in claim 10 wherein said first light source is a linear fluorescent.

12. A lumenaire system as in claim 10 wherein the second light source is the sun.

13. A lumenaire system as in claim 10 wherein said prismatic structure is comprised of substantially linear prisms substantially triangular in structure.

14. In a lumenaire having a light source and an optic system having a refracting function, the improvement comprising:
a component of the light system for providing the refracting function of variably changing the distribution of light rays from the light source entering said component, said component being a flexible plastic film having prism structures, said component having a changeable curvature which is changed by a mechanical force,

15. A lumenaire system as in claim 14 wherein said component comprises linearly disposed prisms substantially triangular in section.

16. A lumenaire system for providing illumination comprising:
an array of light projecting panels for providing a first light source, each said panel including at least one LED light source mounted to a heat sink;
a collimating optic at least partially surrounding each LED, said collimating optic functioning to project light out of at least one edge of said panel;
a second light source;
the array of panels being disposed to form openings between the panels to allow light from said second light source to pass through the openings;
the surfaces of the sides of the light projecting panels including a light controlling material to alter the distribution of light from said second light source passing through the openings between the light projecting panels.

17. A lumenaire as in claim 16 wherein said array of lumenaire panels is in the form of a grid.

18. A lumenaire as in claim 16 wherein said grid acts as a baffle to a light source mounted in proximity to said grid.

19. A lumenaire as in claim 16 wherein said array of lumenaire panels is linear and can rotate on a linear axis so as to change the direction of light projected from linear arrays of panels.

20. A lumenaire as in claim 19 wherein said linear panels can function as louvers and be so disposed as to allow sunlight to pass through, be redirected, or be blocked.
